(19) United States
(12) Patent Application Publication
(10) Pub. No.: US 2026/0291441 A1
(43) Pub. Date: Sep. 24, 2026

(54) POWER AMPLIFICATION AND COUPLING CIRCUIT WITH TRANSFORMER LINE

(71) Applicant: JABIL INC., St.Petersburg, FL (US)

(72) Inventor: Lintao Liu, St. Petersburg, FL (US)

(21) Appl. No.: 19/473,681

(22) PCT Filed: Apr. 10, 2024
(86) PCT No.: PCT/US2024/023774

§ 371 Date: Oct. 8, 2025

Related U.S. Application Data
(60) Provisional application No. 63/458,683, filed on Apr. 12, 2023.

(51) Int. Cl. H03F 1/02; H01P 5/18; H03F 1/32

(52) U.S. Cl. CPC H03F 1/0288; H01P 5/184; H03F 1/3247; H03F 2200/207; H03F 2200/451

(57) ABSTRACT

An apparatus, system and method may include a coupler obeying an equation of a Doherty amplifier, comprising: an input port of a quarter wavelength transformer line having impedance R1; an output port of the quarter wavelength transformer line having impedance R2, wherein the input port and the output port are ends of a main signal line for amplification; a coupling port for providing feedback having impedance R3; and a loaded, isolated port impedance, R4. The amplification obeys the Doherty equation, thereby defining R1 and R2, and R3 and R4 define the coupling, such that: R1/R2=R3/R4. A length allocation of transformer lines that provide the coupling is one quarter wavelength, in order to provide a phase difference between impedances R3 and R4 of 90 degrees. Reflected coefficients are less than minus 20 dB, and directivity is at least 30 dB.

### CROSS-REFERENCE TO RELATED APPLICATION

This application claims the benefit of priority to U.S. Provisional Application No. 63/458,683, filed Apr. 12, 2023, entitled: “Power Amplification and Coupling Circuit with Transformer Line,” the contents of which are incorporated herein by reference as if set forth in its entirety.

### BACKGROUND

### Field of the Disclosure

The present disclosure relates to electrical circuits, and, more specifically, to an apparatus, system and method for a power amplifier and coupling circuit with a transformer line.

### Description of the Background

A Doherty amplifier design is frequently used when a high efficiency power amplifier is needed, such as for high peak to average power ratios. Indeed, the Doherty amplifier is likely the most popular power amplifier design in use today.

Modern radio communication systems frequently use high order quadrature amplitude modulation (QAM) transmissions, which effect a high peak to average power ratio. This characteristic often leads to low efficiency in the use of power amplifiers. The Doherty amplifier, however, provides the required linearity in the RF amplifier while simultaneously providing a significant improvement in power amplifier efficiency.

The Doherty amplifier is a Class AB plus Class C configuration that achieves high efficiency by having two amplifier sections. The first section is operable for lower amplitude signal circumstances. The second section is used to provide a capability to meet higher level signal conditions. Thereby, the Doherty amplifier provides both linearity and efficiency.

The foregoing is a substantial reason for the use of the Doherty power amplifier in a number of circumstances, such as particularly for telecommunications power amplification. The Doherty amplifier improves the linearity of the amplification, especially when used together with digital predistortion technology. However, digital predistortion technologies require a coupler at the output of the power amplifier. The standard coupler size is a quarter-wavelength transmission line.

Of note, there may be one or multiple quarter wavelength impedance transforming lines in a Doherty circuit. Consequently, it has been theorized that the Doherty circuit's quarter wavelength line (or lines) may be used as a coupler, in order to reduce circuit size and complexity. That is, the Doherty circuit would be used for its typical power amplification function, and would additionally be used as a transmission line of coupler.

However, the performance of the Doherty circuit as a transmission line of a coupler is very poor as used in the known art. The directivity of the coupler in this instance is around 10 dB, which is significantly less than the 30 dB directivity of a normal coupler, and the minimum 20 dB desired in the current circumstances. Further, the impedance matching provided by the Doherty circuit as a coupler is similarly poor.

### SUMMARY

The disclosure is and includes an apparatus, system and method for a power amplifier and coupling circuit. The apparatus, system and method may include a coupling circuit of Doherty amplifier obeying the equations of a Doherty amplifier, comprising: an input port of a quarter wavelength transformer line having impedance R1; an output port of the quarter wavelength transformer line having impedance R2, wherein the input port and the output port are ends of a main signal line for amplification; a coupling port for providing feedback having impedance R3; and a loaded, isolated port impedance, R4.

The coupler obeys the equation, thereby defining R1 and R2, and R3 and R4 define the coupling, such that: R1/R2=R3/R4. A length allocation of transformer lines that provide the coupling is one quarter wavelength, in order to provide a phase difference between impedances R3 and R4 of 90 degrees. Reflected coefficients are less than minus 20 dB, and directivity is at least 30 dB.

### BRIEF DESCRIPTION OF THE DRAWINGS

The disclosed non-limiting embodiments are discussed in relation to the drawings appended hereto and forming part hereof, wherein like numerals indicate like elements, and in which:

FIG. 1 illustrates aspects of the embodiments.

### DETAILED DESCRIPTION

The figures and descriptions provided herein may have been simplified to illustrate aspects that are relevant for a clear understanding of the herein described devices, systems, and methods, while eliminating, for the purpose of clarity, other aspects that may be found in typical similar devices, systems, and methods. Those of ordinary skill may recognize that other elements and/or operations may be desirable and/or necessary to implement the devices, systems, and methods described herein. But because such elements and operations are well known in the art, and because they do not facilitate a better understanding of the present disclosure, a discussion of such elements and operations may not be provided herein. However, the present disclosure is deemed to inherently include all such elements, variations, and modifications to the described aspects that would be known to those of ordinary skill in the art.

Embodiments are provided throughout so that this disclosure is sufficiently thorough and fully conveys the scope of the disclosed embodiments to those who are skilled in the art. Numerous specific details are set forth, such as examples of specific components, devices, and methods, to provide a thorough understanding of embodiments of the present disclosure. Nevertheless, it will be apparent to those skilled in the art that certain specific disclosed details need not be employed, and that embodiments may be embodied in different forms. As such, the embodiments should not be construed to limit the scope of the disclosure.

The terminology used herein is for the purpose of describing particular example embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof.

The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc., may be used herein to describe various elements, components, regions, layers and/or sections, these elements, components, regions, layers and/or sections should not be limited by these terms. These terms may be only used to distinguish one element, component, region, layer or section from another element, component, region, layer or section. That is, terms such as “first,” “second,” and other numerical terms, when used herein, do not imply a sequence or order unless clearly indicated by the context. Thus, a first element, component, region, layer or section discussed below could be termed a second element, component, region, layer or section without departing from the teachings of the exemplary embodiments.

In the embodiments, the difficulties in the known art in using the Doherty circuit as a coupler is remedied by defining the impedance relationship of the coupler's ports, and through the use of a coupling line of predetermined length. That is, the embodiments are designed specifically for impedance matching, and the line length is thus designed specifically as a one-quarter wavelength. The embodiments as provided may provide drastically improved impedance matching over the known art, as well as 30 dB to 40 dB of directivity, by way of non limiting example.

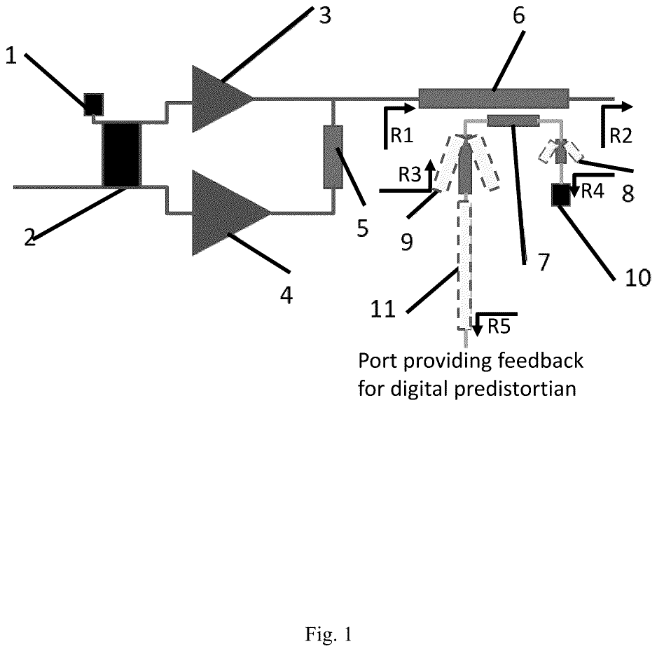

FIG. 1 illustrates the use of a Doherty circuit as a coupling amplifier. As illustrated, R1 is the impedance of the input port of the Doherty's quarter wavelength transformer line, which line is a main signal line of the provided coupler. R2 is the impedance of the output port of the Doherty's quarter wavelength transformer line, which is also a main signal line of the coupler. R3 is the impedance of the coupling port of the coupler, which provides feedback to the digital predistortion. R4 is an isolated port impedance of the coupler, which may typically be loaded by a resistance

Accordingly, R1 and R2 are part of the Doherty amplifier design, with values decided by the equations of a Doherty amplifier. The coupler side of the illustrated embodiment is provided by R3 and R4.

More specifically the relationship of the impedances follows the equation:

R1/R2=R3/R4.

Further, lines 8, 9 are needed to provide the disclosed impedance transformer. The length allocation between lines 7, 8, and 9 may be flexible, but the total length allocated must be one quarter wavelength in order to provide a phase difference between R3 and R4 of 90 degrees. With these design constraints, the matching at the coupler's ports is much improved over the known art. Reflected coefficients are less than minus 20 dB, and the directivity is at least 30 dB.

R5, which is the impedance of the coupling port to the digital domain, and the output port R2, may preferably be 50 ohms in the disclosed design. Accordingly, using the equation above, the coupler's load 10 is:

$$\begin{matrix}R 4 = R 2 / R 1 \times R 3 \\ = 50 / R 1 \times 50 \\ = 2500 / R 1\end{matrix}$$

Additionally and alternatively, the coupler's load 10, as illustrated, may be set to 50 ohms, then R3 will be:

$$\begin{matrix}R 3 = R 1 / R 2 \times R 4 = \\ = R 1 / 50 \times 50 \\ = R 1\end{matrix}$$

And thus R3 will be equal to R1.

An additional quarter wavelength impedance transformer line 11 may be provided to convert R3 to a standard 50 ohm resistance.

From the above, several design considerations become evident. R4 is normally the load, but may be flexible or may be set to 50 ohms. Further, because R3 is usually lower than R4, a higher resistance may be preferable for R4 certain embodiments. R5 receives the transfer to it of R3, and R5 is the output port. Thus, R3, R4 and R5 provide the transformer line, and R4 may be flexible. Therefore, one can design from R3 to obtain R4, or from R4 to obtain R3.

In additional aspects of FIG. 1, 50 ohm load 1 may be associated with an input power divider of the Doherty circuit 2. This divides input power into two pipelines.

Main amplifier 3 may carry most of the signal energy of the Doherty circuit. Peak amplifier 4 may carry peak power signals of the Doherty circuit. Peak offset line 5 may be provided such that the Doherty peak amplification 4 optimally operates. The Doherty circuit's impedance transformer line 6 also serves as the coupler's main signal line.

Coupling line 7 couples the main Doherty circuit to the output port. Matching lines 8, 9 improve the impedance matching of the disclosed embodiments, as discussed throughout. Load 10 provides resistance R4. Impedance transformer line 11 may transform impedance from a low impedance to a standard 50 ohm resistance. R1, R2, R3, and R4 are the coupler's four ports and provide the relationship discussed throughout. R5 is the impedance of the output port to the digital domain.

In the foregoing detailed description, it may be that various features are grouped together in individual embodiments for the purpose of brevity in the disclosure. This method of disclosure is not to be interpreted as reflecting an intention that any subsequently claimed embodiments require more features than are expressly recited.

Further, the descriptions of the disclosure are provided to enable any person skilled in the art to make or use the disclosed embodiments. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but rather is to be accorded the widest scope consistent with the principles and novel features disclosed herein.

In the foregoing Detailed Description, it can be seen that various features are grouped together in a single embodiment for the purpose of clarity and brevity of the disclosure. This method of disclosure is not to be interpreted as reflecting an intention that the embodiments require more features than are expressly recited herein. Rather, the disclosure is to encompass all variations and modifications to the disclosed embodiments that would be understood to the skilled artisan in light of the disclosure.

What is claimed is:

1. A coupler obeying an equation of a Doherty amplifier, comprising:
an input port of a quarter wavelength transformer line having impedance R1;
an output port of the quarter wavelength transformer line having impedance R2, wherein the input port and the output port are ends of a main signal line for amplification;
a coupling port for providing feedback having impedance R3;
a loaded, isolated port impedance, R4;
wherein the amplification obeys the equation, thereby defining R1 and R2, and R3 and R4 define the coupling, such that:
$$R 1 / R 2 = R 3 / R 4 ;$$
and
wherein:
a length allocation of transformer lines that provide the coupling is one quarter wavelength, in order to provide a phase difference between impedances R3 and R4 of 90 degrees;
reflected coefficients are less than minus 20 dB; and
directivity is at least 30 dB.
